(19) United States
(12) Patent Application Publication
(10) Pub. No.: US 2010/0003422 A1
(43) Pub. Date: Jan. 7, 2010

(54) DEPOSITION APPARATUS, FILM MANUFACTURING METHOD, AND MAGNETIC RECORDING MEDIUM MANUFACTURING METHOD

(75) Inventors: Norikazu NAKAMURA, Kawasaki (JP); Shoichi MIYAHARA, Kawasaki (JP); Yukiko OSHIKUBO, Kawasaki (JP); Hiroshi CHIBA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/480,195

(22) Filed: Jun. 8, 2009

(30) Foreign Application Priority Data
Jul. 4, 2008 (JP) 2008-175784

(51) Int. Cl. C23C 16/50

(52) U.S. Cl. 427/571; 118/723 E; 427/569

(57) ABSTRACT

A deposition apparatus includes a plasma generating unit that generates an arc discharge between a target and an anode to generate plasma; a deposition chamber in which a base is disposed; and a plasma transfer unit that transfers the plasma to the deposition chamber, wherein at least part of the plasma transfer unit is electrically separated from the plasma generating unit and the deposition chamber, and a negative voltage is applied to at least part of the plasma transfer unit.

### CROSS-REFERENCE TO RELATED APPLICATIONS

This application claims the benefit of priority from Japanese Patent Application No. 2008-175784 filed on Jul. 4, 2008, the entire contents of which are incorporated herein by reference.

### BACKGROUND

1. Field

The embodiments discussed herein relate to a deposition apparatus that manufactures a protective film for protecting a surface of a magnetic recording medium used in a magnetic recording apparatus.

2. Description of Related Art

A magnetic recording apparatus such as a hard disk drive is used in information devices such as a computer and a hard disk video recorder.

In the magnetic recording apparatus, a recording layer of a disc-shaped magnetic recording medium, for example, magnetic disk, which rotates at high speed, is magnetized with a recording element, for example, write head, thereby recording data. The data recorded in the magnetic recording medium is read with a reproduction element, for example, read head, and the read data is converted into an electric signal and is output.

The recording layer of the magnetic recording medium includes a cobalt alloy having good magnetic properties. However, because the cobalt alloy has insufficient durability and corrosion resistance, deterioration of the properties and mechanical or chemical damage occur by contact with the magnetic head, friction or abrasion by slide, and corrosion by moisture adsorption. Therefore, the protective film in which a lubricant is applied on the recording layer is formed to ensure the durability and the corrosion resistance.

For example, the protective film of the magnetic recording medium includes silicon oxide (SiO₂), silicon nitride (SiNₓ), or aluminum oxide (Al₂O₃). A carbon protective film, for example, a protective film mainly containing carbon is also used because of excellent heat resistance, corrosion resistance, and abrasion resistance. The carbon protective film is formed by a sputtering method or a Chemical Vapor Deposition (CVD) method.

For example, Takigawa et al. Surface and Coatings Technology 163-164, 368 (2003), Japanese Laid-open Patent Publication Nos. 2005-216575, 2002-8893, 2005-158092, and 2003-160858, and Japanese Patent No. 3860954 disclose the formation of the protective film.

### SUMMARY

According to one aspect of embodiments, a deposition apparatus is provided which includes a plasma generating unit that generates an arc discharge between a target and an anode to generate plasma; a deposition chamber in which a base is disposed; and a plasma transfer unit that transfers the plasma to the deposition chamber, wherein at least part of the plasma transfer unit is electrically separated from the plasma generating unit and the deposition chamber, and a negative voltage is applied to at least part of the plasma transfer unit. Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates a first embodiment;

FIG. 2 illustrates an exemplary specimen;

FIG. 3 illustrates an exemplary relationship between a voltage applied to a negative-voltage applying unit and a number of particles included in one substrate;

FIG. 4 illustrates an exemplary measurement result of film density of a carbon film; and

FIG. 5 illustrates a second embodiment.

### DESCRIPTION OF PREFERRED EMBODIMENTS

A distance (magnetic spacing) between a recording layer of a magnetic recording medium and the magnetic head is shortened with increasing capacity of a magnetic recording apparatus. Therefore, there is a need to thin a carbon protective film.

Since sufficient durability and corrosion resistance are not ensured when the carbon protective film has the thickness of 3 nm or less, it is preferable that a thickness of the carbon protective film, which is formed by the CVD method, be at least 4 nm. Therefore, the formation of the carbon protective film by a Filtered Cathodic Arc (FCA) method in which an arc is used as a plasma source is discussed.

In the FCA method, an arc discharge whose discharge point temperature is 10,000° C. or more is utilized, so that carbon having high heat resistance is easily melted or sublimated. The FCA method differs from the CVD method in that deposition is performed with a material containing only carbon.

Because the carbon protective film formed by the FCA method has a high rate of sp3 bond component, the carbon protective film formed by the FCA method has a high density and high hardness compared with the carbon protective film formed by the CVD method. A carbon protective film having a thickness of 2 nm, formed by the FCA method, has a durability substantially equal to or more than that of a carbon protective film having a thickness of 4 nm, formed by a CVD method. Hereinafter an apparatus in which the deposition is performed by the FCA method is referred to as an FCA deposition apparatus.

In the FCA method, because the plasma is generated by the arc discharge, carbon particles, for example, fine particles (called macro particle) having diameters of about 0.01 to several hundred μm are generated when the carbon protective film is formed. Therefore, the particles adhere to a surface of the magnetic recording medium in forming the protective film. When the magnetic recording medium to which the particles adhere is used in the magnetic recording apparatus, the magnetic head contacts the particles in recording or reproducing data, which damages the magnetic head. Further, the particles are taken off from the magnetic recording medium, and voids are generated in portions from which the particles are taken off, which deteriorates durability and corrosion resistance.

In the FCA deposition apparatus, for example, the plasma and the electrically-neutral particles are separated using a magnetic field filter. However, charged particles may be generated in the arc discharge. Because the traveling directions of some charged particles are curved by the magnetic field filter, the particles are moved in the same direction as the plasma, and adhere to a specimen surface. Therefore, there is a demand for a good thin film having a few particles.

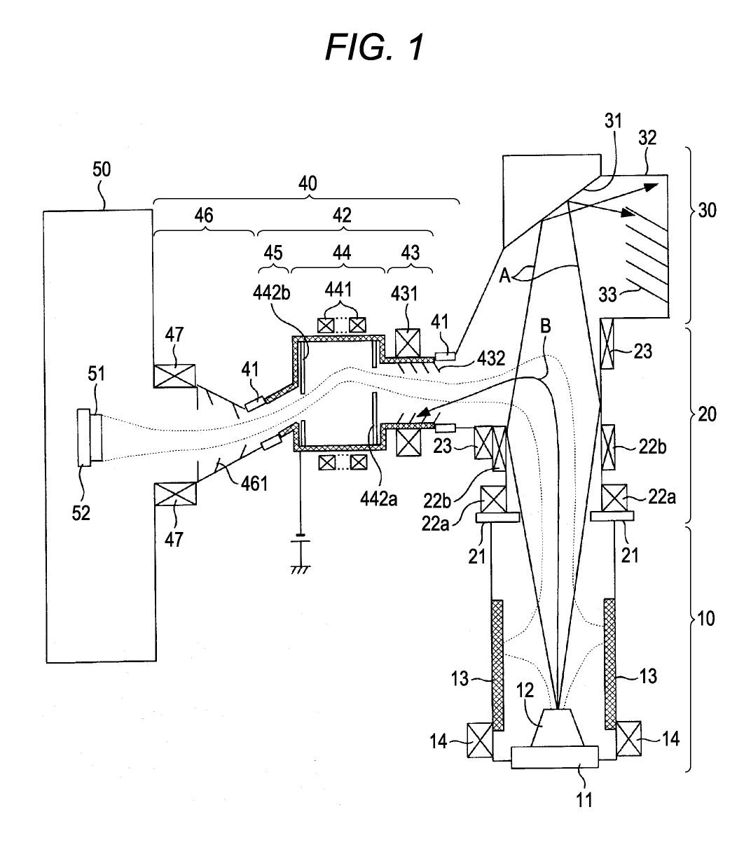

FIG. 1 illustrates a first embodiment. The deposition apparatus of the first embodiment includes a plasma generating unit 10, a plasma separating unit 20, a particle trapping unit 30, a plasma transfer unit 40, and a deposition chamber 50. The chassis of the plasma generating unit 10, the plasma separating unit 20, the particle trapping unit 30, the plasma transfer unit 40, and the deposition chamber 50 include metal such as stainless steel.

The plasma generating unit 10, the plasma separating unit 20, and the particle trapping unit 30 have a cylindrical shape. The plasma generating unit 10, the plasma separating unit 20, and the particle trapping unit 30 are linearly arranged and coupled in that order from the bottom.

The plasma transfer unit 40 also has a cylindrical shape, one of the ends of the plasma transfer unit 40 is substantially perpendicularly coupled to the plasma separating unit 20, and the other end is coupled to the deposition chamber 50. The deposition chamber 50 includes a stage 52 on which a substrate (base) 51 is provided.

An insulation plate 11 is provided at a lower end of the chassis of the plasma generating unit 10. A target (cathode) 12 is provided on the insulation plate 11. A cathode coil 14 is provided in an outer circumference at the lower end of the chassis of the plasma generating unit 10. An anode 13 is provided in an inner wall surface of the chassis. During the deposition, a power supply (not illustrated) applies a given voltage between the target 12 and the anode 13 to generate the arc discharge, and the plasma is generated above the target 12. In order to stabilize the arc discharge, the power supply supplies a given current to the cathode coil 14 to generate a magnetic field.

A component of the target 12 is vaporized by the arc discharge, thereby supplying a deposition material ion into the plasma. Therefore, preferably the target 12 contains the deposition material. In the first embodiment, graphite is used as the target 12 because a carbon protective film is formed on the substrate 51. The plasma generating unit 10 includes a trigger electrode (not illustrated) that applies a voltage for triggering the arc discharge. A reactive gas or an inert gas is supplied to the plasma generating unit 10 if needed.

As illustrated in FIG. 1, the plasma separating unit 20 has a diameter smaller than that of the plasma generating unit 10. An insulation ring 21 is provided at a boundary between the plasma generating unit 10 and the plasma separating unit 20. The insulation ring 21 electrically separates the chassis of the plasma generating unit 10 from the chassis of the plasma separating unit 20. For example, the insulation ring 21 includes fluororesin having excellent insulation properties.

Guide coils 22a and 22b are provided in the outer circumference of the chassis of the plasma separating unit 20. The guide coil 22a and 22b generate the magnetic fields. The magnetic fields cause the plasma generated by the plasma generating unit 10 to move in a given direction while converging it in a central portion of the chassis. An oblique magnetic field generating coil 23 is provided near a connection portion between the plasma separating unit 20 and the plasma transfer unit 40 in order to generate a magnetic field (hereinafter referred to as an “oblique magnetic field”) that curves a traveling direction of the plasma by about 90°.

Particles generated in the plasma generating unit 10 go straight into the particle trapping unit 30 without being substantially influenced by the magnetic field of the plasma separating unit 20. A reflecting plate 31 and a particle capture unit 32 are provided at the top of the particle trapping unit 30. The reflecting plate 31 reflects the particles in a horizontal direction. The particle capture unit 32 captures the particles reflected from the reflecting plate 31. In the particle capture unit 32, plural fins 33 are obliquely arranged with respect to an inner surface of the chassis. The particles, which enter the particle capture unit 32, are reflected many times by the plural fins 33 to lose kinetic energy, and are finally captured by the fins 33 or the chassis wall surface.

The plasma separated from the particles by the plasma separating unit 20 goes into the plasma transfer unit 40. The plasma transfer unit 40 is partitioned into a negative-voltage applying unit 42 and a communication unit 46. An insulation ring 41 is provided between the negative-voltage applying unit 42 and the plasma separating unit 20, and an insulation ring 41 is also provided between the negative-voltage applying unit 42 and the communication unit 46. As with the insulation ring 21, the insulation ring 41 includes a material such as fluororesin having excellent insulation properties. The insulation rings 41 electrically divide the negative-voltage applying unit 42 into the plasma generating unit 10, the plasma separating unit 20, and the deposition chamber 50. A voltage that is lower than a ground voltage (0 V) by about 5 to about 15 V is applied to the negative-voltage applying unit 42.

The negative-voltage applying unit 42 is partitioned into an entrance portion 43 on the side of the plasma separating unit 20, an exit portion 45 on the side of the communication unit 46, and an intermediate portion 44 between the entrance portion 43 and the exit portion 45. A guide coil 431 is provided in the outer circumference of the entrance portion 43. The guide coil 431 generates a magnetic field. The magnetic field causes the plasma to move toward the side of the deposition chamber 50 while converging it. In the entrance portion 43, plural fins 432 are obliquely arranged with respect to the inner surface of the chassis. The plural fins 432 capture the particles going into the entrance portion 43.

As illustrated in FIG. 1, the intermediate portion 44 has a diameter larger than those of the entrance portion 43 and exit portion 45. In the intermediate portion 44, shield plates (apertures) 442a and 442b are disposed on the side of the entrance portion 43 and on the side of the exit portion 45, respectively. The shield plates (apertures) 442a and 442b include openings that regulate a channel of the plasma. The opening of the shield plate 442a is disposed on the relatively upper side while the opening of the shield plate 442b is disposed on the relatively lower side. A guide coil 441 is provided in the outer circumference of the intermediate portion 44. The guide coil 441 generates a magnetic field that curves the traveling direction of the plasma.

In the first embodiment, because a space may be needed to curve the traveling direction of the plasma, the intermediate portion 44 has the diameter larger than those of the entrance portion 43 and exit portion 45. The particles, which enter the intermediate portion 44, are repeatedly reflected in the intermediate portion 44 to lose the kinetic energy, and are easily adsorbed by the wall surface of the intermediate portion 44.

The entrance portion 43 and the intermediate portion 44 are coaxially disposed, while the exit portion 45 is projected obliquely downward from the opening of the shield plate 442b.

The communication unit 46 is formed such that the diameter of the communication unit 46 is gradually increased from the side of the negative-voltage applying unit 42 toward the deposition chamber 50. Plural fins 461 are also arranged in the communication unit 46. A guide coil 47 is provided in an outer circumference at a boundary between the communication unit 46 and the deposition chamber 50. The guide coil 47 generates a magnetic field. The magnetic field causes the plasma to move toward the side of the deposition chamber 50 while converging it.

The deposition chamber 50 includes the stage 52 on which the substrate 51 is placed. A surface (deposition surface) of the substrate 51 is disposed toward a direction in which the plasma flows. The stage 52 may include a mechanism that inclines the substrate 51 with respect to the plasma inflow direction or a mechanism that rotates the substrate 51. A vacuum apparatus (not illustrated) is coupled to the deposition chamber 50. The vacuum apparatus maintains the inner space of the deposition apparatus at a given pressure. Examples of the substrate 51 include a magnetic recording medium substrate in which a recording layer (magnetic layer) has been formed and a magnetic head substrate in which the recording element and the reproduction element have been formed.

The particles adhere to the fins 33, 432 and 461 and the shield plate 442a and 442b with the deposition. With increasing particle adhesion amount, the particles may take off from the fins 33, 432, and 461 or the shield plates 442a and 442b and move onto the side of the deposition chamber 50 for some reason. Therefore, desirably the fins 33, 432, and 461 and the shield plates 442a and 442b are easily exchanged for others. The chassis of the negative-voltage applying unit 42 may be exchanged.

The graphite target is used as the target 12 when the carbon film is formed on the substrate 51. The vacuum apparatus maintains the pressure in the deposition apparatus in the range of 10⁻⁵ Pa to 10⁻³ Pa. For example, the plasma is generated under the conditions of an arc current of 120 A, an arc voltage of 25 V, and a cathode coil current of 10 A. The plasma includes the carbon ions.

The plasma generated with the plasma generating unit 10 goes into the plasma separating unit 20. The magnetic fields generated with the guide coils 20a and 20b move the plasma to the neighborhood of the connection portion with the plasma transfer unit 40. The oblique magnetic field generated by the oblique magnetic field generating coil 23 largely curves the traveling direction of the plasma, and the plasma goes into the plasma transfer unit 40. Broken lines in FIG. 1 indicate a plasma moving path.

Large numbers of the particles generated by the arc discharge in the plasma generating unit 10 have no charge or have a small charge relative to their weight. Therefore, the particles go straight without being substantially influenced by the magnetic fields generated with the guide coils 22a and 22b and the oblique magnetic field generating coil 23. The particles are reflected in the horizontal direction by reflecting plate 31 in the particle trapping unit 30, and are captured by the fins 33 of the particle capture unit 32. Arrows A of FIG. 1 indicate a particle moving direction.

Large numbers of the particles generated with the plasma generating unit 10 go into the particle trapping unit 30, and the particles are captured by the fins 33 of the particle capture unit 32. However, small numbers of the particles having positive charges go into the plasma transfer unit 40 along with the plasma since the traveling direction is curved by the magnetic field generated by the oblique magnetic field generating coil 23. Small numbers of the particles that are repeatedly reflected in the inner surface of the chassis also go into the plasma transfer unit 40. Among the particles, the particles that are repeatedly reflected in the inner surface of the chassis are captured by the fins 432 and the shield plates 442a and 442b, and do not reach the deposition chamber 50.

The negative-voltage applying unit 42 applies the negative voltage (−5 V to −15 V) to the positively-charged particles that go into the negative-voltage applying unit 42 along with the plasma. Therefore, as illustrated by an arrow B of FIG. 1, the particles are separated from the plasma and headed to the wall surface of the negative-voltage applying unit 42, and are captured by the wall surface of the negative-voltage applying unit 42 and the fins 432. In the first embodiment, because the plasma transfer path is set in non-linear shape but the complicated curved shape in the plasma transfer unit 40, the particle having a mass larger than that of a gaseous deposition component is prevented from moving along with the plasma, and the plasma and the particle are securely separated.

Because the plasma passing through the negative-voltage applying unit 42 enters the deposition chamber 50 through the communication unit 46, the carbon is deposited on the substrate 51 to form the carbon film. The fins 461 are also provided in the inner surface of the communication unit 46, and large numbers of the particles passing through the negative-voltage applying unit 42 are captured by the fins 461.

In the first embodiment, the fins 432 and 461 and the shield plates 442a and 442b capture the particles that are reflected by the inner surface of the chassis and moved to the side of the deposition chamber 50. In the first embodiment, the negative-voltage applying unit 42 provided in part of the plasma transfer unit 40 separates the particles having the positive charges from the plasma, and the particles having the positive charges are captured by the fins 432, the shield plates 442a and 442b, and the chassis wall surface. Therefore, because the particles are prevented from going into the deposition chamber 50, the high-quality and high-density carbon film including few particles is formed on the substrate 51.

For example, the voltage applied to the negative-voltage applying unit 42 is set to −15 V, −10 V, −5 V, 0 V, +5 V, +10 V, and +15 V, and the carbon film is formed on a specimen. As to the deposition conditions, the arc current is set to about 120 A and the arc voltage is set to about 25 V.

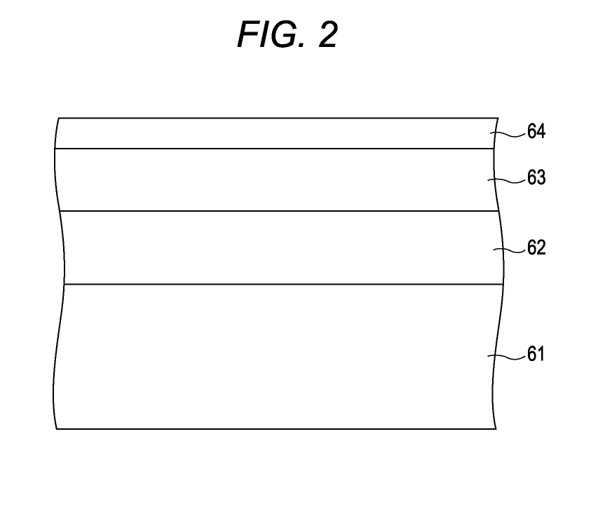

For example, the specimen includes a magnetic recording medium glass substrate having a diameter of 2.5 inches (about 64 mm). As illustrated in FIG. 2, an underlying layer 62 including the magnetic material and a recording layer 63 including, for example, the Co alloy layer are formed on the substrate 61. A carbon film 64 having a thickness of 3 nm is formed on the recording layer 63 using the deposition apparatus. The target 12 contains graphite, for example.

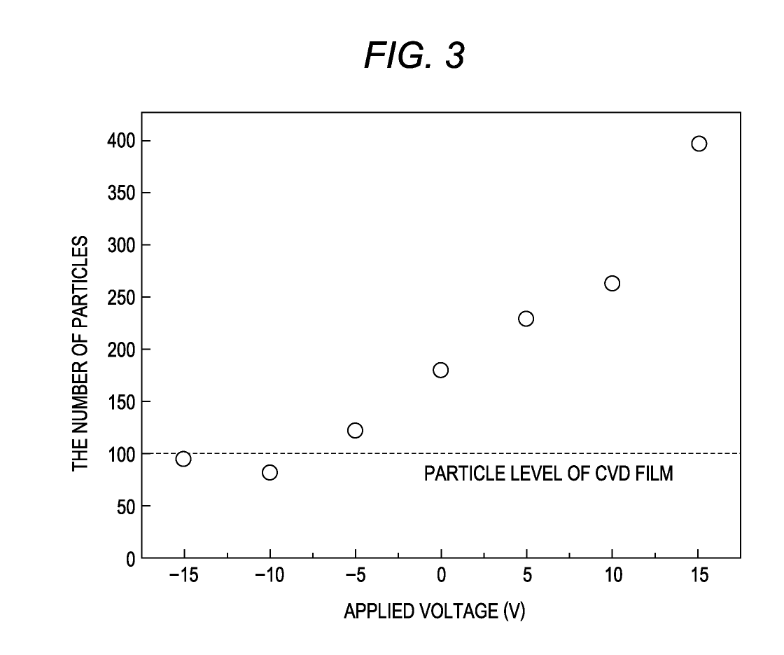

After the carbon film is formed, the number of particles is measured with a particle counter, for example, OSA-5100 (manufactured by CANDELA Instruments). FIG. 3 illustrates an exemplary relationship between a voltage applied to the negative-voltage applying unit 42 and a number of particles included in one substrate. In FIG. 3, a horizontal axis indicates the voltage applied to the negative-voltage applying unit 42. A vertical axis indicates the number of particles included in one substrate. The broken line of FIG. 3 indicates the number of particles, for example, about 100 particles that are included in the carbon film deposited by a usual CVD method per one 2.5-inch substrate.

Assuming that the voltage applied to the negative-voltage applying unit 42 is set in the range of −5 V to −15 V, FIG. 3 illustrates that the number of particles adhering to the carbon film is substantially equal to or lower than that of the carbon film deposited by the CVD method. When the voltage applied to the negative-voltage applying unit 42 is set to −10 V, the number of particles adhering to the carbon film becomes the minimum. As illustrated in FIG. 3, when the voltage is not applied to the negative-voltage applying unit 42, for example, when the voltage is 0 V, the number of particles included in one substrate becomes about 200.

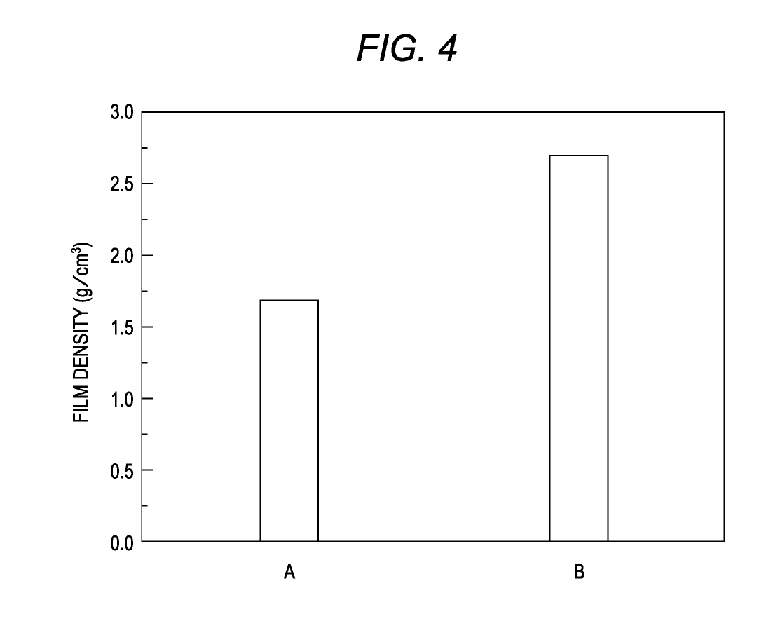

FIG. 4 illustrates an exemplary measurement result of film density of a carbon film. The letter A of FIG. 4 designates the measurement result of the film density of the carbon film formed with the deposition apparatus of the first embodiment. The letter B of FIG. 4 designates the measurement result of the film density of the carbon film formed by the CVD method. The film density is measured by Rutherford back scattering spectroscopy. The carbon film formed by the deposition apparatus of the first embodiment has the film density of about 2.7 g/cm³, and has the film density at least about 1.5 times the film density (about 1.7 g/cm³) of the carbon film formed by the CVD method.

The high-quality carbon film having the high film density and extremely few particles is formed in the first embodiment. The durability of the magnetic recording medium or magnetic head is improved using the carbon film as the protective film of the magnetic recording medium or magnetic head.

In the first embodiment, the voltage applied to the negative-voltage applying unit 42 is the direct-current voltage. Alternatively, an alternating-current voltage, which biases to the negative side, or a pulse voltage may be used. In the first embodiment, the metal is exposed to the chassis inner surface of the negative-voltage applying unit 42. Alternatively, the chassis inner surface may be covered with an insulation film.

In the first embodiment, the negative voltage is applied to the whole of the negative-voltage applying unit 42. Alternatively, for example, the negative voltage may be applied to the shield plates 442a and 442b. Although the negative voltage may also be applied to the communication unit 46, the flow of the plasma moving to the deposition chamber 50 may be disturbed when the negative voltage is applied to the communication unit 46. Therefore, desirably the negative voltage is applied to a portion located away from the deposition chamber 50.

Desirably blasting, for example, a process for forming fine irregularities is performed to the inner surface of the negative-voltage applying unit 42. This is because the particles colliding with the inner surface of the negative-voltage applying unit 42 are randomly reflected so that the movement of the particles onto the side of the deposition chamber 50 is prevented.

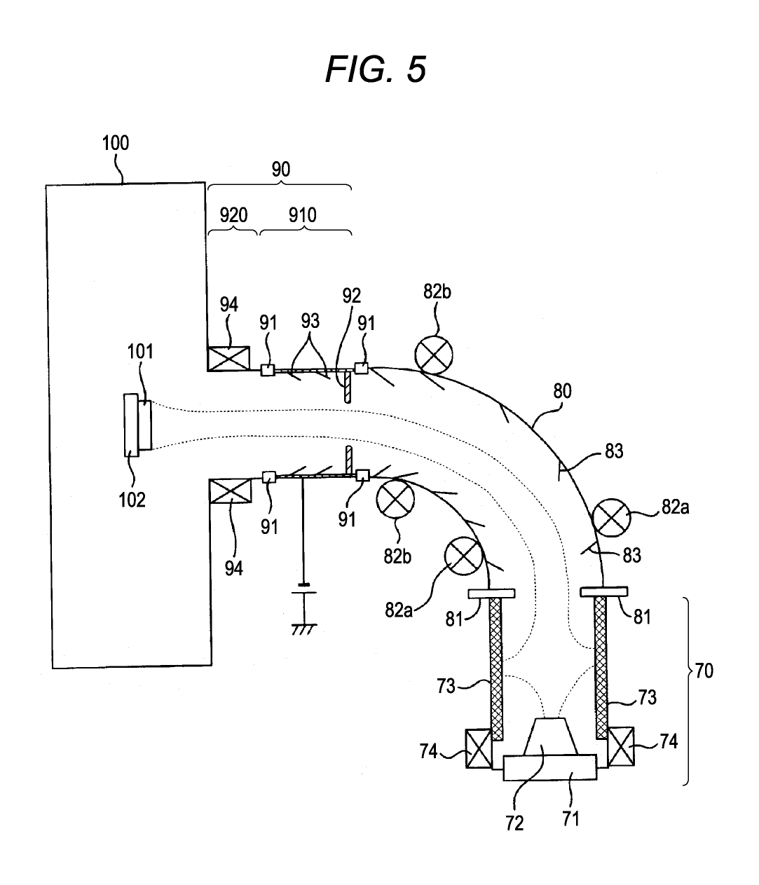

FIG. 5 illustrates a second embodiment. Broken lines of FIG. 5 indicate the plasma moving path.

As illustrated in FIG. 5, the deposition apparatus of the second embodiment includes a plasma generating unit 70, a plasma separating unit 80, a plasma transfer unit 90, and a deposition chamber 100. The chassis of the plasma generating unit 70, plasma separating unit 80, plasma transfer unit 90, and deposition chamber 100 may contain metal such as stainless steel.

As with the first embodiment, the plasma generating unit 70 includes an insulation plate 71, a target (cathode) 72, an anode 73, and a cathode coil 74. A given voltage is applied between the target 72 and the anode 73 to generate the plasma above the target 72. A magnetic field which stabilizes the plasma is generated by supplying a given current to the cathode coil 74.

The cylindrical plasma separating unit 80 has an arc shape that curves at an angle of about 90°. An insulation ring 81 is provided at a boundary between the plasma separating unit 80 and the plasma generating unit 70, and the insulation ring 81 includes a material such as fluororesin having excellent insulation properties. Plural guide coils, for example, two guide coils 82a and 82b of FIG. 5 are provided in the outer circumference of the chassis of the plasma separating unit 80. The guide coils 82a and 82b generate the magnetic field. The magnetic field causes the plasma, generated by the plasma generating unit 70, to move onto the side of the deposition chamber 100 while converging it to the central portion of the chassis. The inner side of the plasma separating unit 80 includes plural fins 83 that are obliquely arranged with respect to the inner surface of the plasma separating unit 80.

The plasma transfer unit 90 is partitioned into a negative-voltage applying unit 910 on the side of the plasma separating unit 80 and a communication unit 920 on the side of the deposition chamber 100. An insulation ring 91 is provided between the negative-voltage applying unit 910 and the plasma separating unit 80, and an insulation ring 91 is also provided between the negative-voltage applying unit 910 and the communication unit 920. As with the insulation ring 81, the insulation ring 91 includes an insulation material such as fluororesin. The insulation ring 91 electrically separates the negative-voltage applying unit 910 from the plasma separating unit 80 and the deposition chamber 100. As with the first embodiment, the voltage that is lower than the ground voltage by about 5 V to about 15 V is applied to the negative-voltage applying unit 910.

An shield plate (aperture) 92 having an opening is provided on the entrance side of the negative-voltage applying unit 910. The opening of the shield plate (aperture) 92 regulates the plasma channel. Plural fins 93 that are obliquely arranged with respect to the inner surface of the chassis are provided inside the negative-voltage applying unit 910.

The communication unit 920 is disposed between the negative-voltage applying unit 910 and the deposition chamber 100. A guide coil 94 is provided in the outer circumference of the chassis of the communication unit 920, and generates the magnetic field to transfer the plasma passing through the negative-voltage applying unit 910 into the deposition chamber 100. As with the first embodiment, the deposition chamber 100 includes a stage 102 on which a substrate 101 to be deposited is placed.

In the second embodiment, graphite is used as the target 72.

For example, the pressure in the deposition apparatus is maintained in the range of 10⁻⁵ Pa to 10⁻³ Pa. A given voltage is applied between the target 72 and the anode 73 and to the cathode coil 74, or a given current is supplied between the target 72 and the anode 73 and to the cathode coil 74, thereby generating the plasma.

The plasma generated by the plasma generating unit 70 goes into the plasma separating unit 80. The plasma is moved to the side of the deposition chamber 100 along the curve of the chassis by the magnetic fields generated by guide coils 82a and 82b while converging in the central portion of the chassis.

In the plasma generating unit 70, the particles generated by the arc discharge go straight through the chassis without being substantially influenced by the magnetic fields generated by the guide coils 81 and 82. Large numbers of particles are repeatedly reflected by the inner wall of the plasma separating unit 80, the fins 83, or the shield plate 92 provided in the entrance portion of the negative-voltage applying unit 90, and the particles are finally captured by the wall surface of the plasma separating unit 80, the fins 83, or the shield plate 92 of the negative-voltage applying unit 90.

Small numbers of particles having a positive charge are moved along with the plasma, and go into the chassis of the negative-voltage applying unit 910 through the opening of the shield plate 92. However, because the negative voltage is applied to the chassis of the negative-voltage applying unit 910, the particles having positive charges are separated from the plasma, and are captured by the fins 93 provided in the chassis of the negative-voltage applying unit 910 or the chassis wall surface.

The plasma from which the particles are removed enters the deposition chamber 100, and carbon is deposited on the substrate 101 to form the carbon film.

In the second embodiment, the particles having the positive charges are separated from the plasma by the negative-voltage applying unit 910 provided in part of the plasma transfer unit 90, and are captured by the fins 93 and the chassis wall surface. The particles are prevented from going into the deposition chamber 100, and the high-quality and high-density carbon film including no particles or few particles is formed on the substrate 101.

In the first and second embodiments, the carbon film is formed on the substrate. However, the deposition apparatus of the first and second embodiments is not limited to the formation of the carbon film, but the deposition apparatus may be used to form films which include various materials.

Example embodiments of the present invention have now been described in accordance with the above advantages. It will be appreciated that these examples are merely illustrative of the invention. Many variations and modifications will be apparent to those skilled in the art.

1. A deposition apparatus comprising:
a plasma generating unit that generates an arc discharge between a target and an anode to generate plasma;
a deposition chamber in which a base is disposed; and
a plasma transfer unit that transfers the plasma to the deposition chamber,
wherein at least part of the plasma transfer unit is electrically separated from the plasma generating unit and the deposition chamber, and a negative voltage is applied to at least part of the plasma transfer unit.

2. The deposition apparatus according to claim 1, wherein the negative voltage ranges from −5 V to −15 V.

3. The deposition apparatus according to claim 1, wherein an outer circumference of a chassis of the plasma transfer unit includes a coil that generates a magnetic field, the magnetic field causing a plasma transfer path to curve within the plasma transfer unit.

4. The deposition apparatus according to claim 3, wherein a diameter of a portion where the coil is provided is larger than diameters of other portions of the plasma transfer unit.

5. The deposition apparatus according to claim 1, wherein the plasma transfer unit includes an shield plate having an opening corresponding to a plasma transfer path.

6. The deposition apparatus according to claim 1, wherein the plasma transfer unit is partitioned into a negative-voltage applying unit on the plasma generating unit side and a communication unit on the deposition chamber side, and wherein a negative voltage is applied to the negative-voltage applying unit.

7. The deposition apparatus according to claim 6, wherein a diameter of a portion on the deposition chamber side of the communication unit is larger than a diameter of a portion on the negative-voltage applying unit side.

8. The deposition apparatus according to claim 6, wherein the negative-voltage applying unit is exchangeable.

9. The deposition apparatus according to claim 1, wherein an inner wall surface of the plasma transfer unit includes a plurality of fins.

10. The deposition apparatus according to claim 1, further comprising:
a particle separating unit, provided between the plasma generating unit and the plasma transfer unit, that separates the plasma from a particle by using a magnetic field.

11. The deposition apparatus according to claim 10, further comprising:
a particle trapping unit that captures the particle separated by the particle separating unit.

12. A film manufacturing method comprising:
generating an arc discharge between a target and an anode to generate plasma;
transferring the plasma to a deposition chamber through a plasma transfer unit;
forming a film by adhering an ion included in the plasma onto a base in the deposition chamber; and
electrically separating at least part of the plasma transfer unit from the plasma generating unit and the deposition chamber, and
applying a negative voltage to at least part of the plasma transfer unit.

13. The film manufacturing method according to claim 12, wherein graphite is used as the target.

14. The film manufacturing method according to claim 12, wherein the base includes at least one of a substrate for a magnetic recording medium and a substrate for forming a magnetic head.

15. The film manufacturing method according to claim 12, wherein the negative voltage ranges from −5 V to −15 V.

16. The film manufacturing method according to claim 12, wherein the negative voltage includes one of an alternating-current voltage, which is negatively biased, and a pulse voltage.

17. The film manufacturing method according to claim 12, wherein a magnetic field is applied to the plasma passing through the plasma transfer unit, wherein the magnetic field causes a plasma transfer path to curve.

18. The film manufacturing method according to claim 12, wherein the plasma transfer unit includes an shield plate having an opening corresponding to a plasma transfer path.

19. The film manufacturing method according to claim 12, wherein the plasma transfer unit is partitioned into a negative-voltage applying unit on the plasma generating unit side and a communication unit on the deposition chamber side, and
the negative voltage is applied to the negative-voltage applying unit.

20. A magnetic recording medium manufacturing method for manufacturing a magnetic recording medium with a deposition apparatus including a plasma generating unit, a plasma transfer unit, and a deposition chamber,
the method comprising:
disposing a substrate in the deposition chamber, wherein a magnetic film is formed on the substrate;
generating an arc discharge between a target containing carbon and an anode in order to generate plasma in the plasma generating unit;
transferring the plasma generated in the plasma generating unit to the deposition chamber through the plasma transfer unit while a negative voltage is applied to at least part of the plasma transfer unit; and
depositing carbon included in the plasma on the substrate to form a carbon film.
